(19) United States
(12) Patent Application Publication
(10) Pub. No.: US 2009/0278171 A1
(43) Pub. Date: Nov. 12, 2009

(54) High linearity doped-channel FET

(75) Inventors: Iris Hsieh, Tao Yuan Shien (TW); Jeff Yeh, Tao Yuan Shien (TW); Cheng-Guan Yuan, Tao Yuan Shien (TW); Yu Chi Wang, Tao Yuan Shien (TW)

Correspondence Address: BACON & THOMAS, PLLC, 625 SLATERS LANE, FOURTH FLOOR, ALEXANDRIA, VA, 22314-1176, US

(73) Assignee: WIN Semiconductors Corp., Tao Yuan Shien (TW)

(21) Appl. No.: 12/149,862

(22) Filed: May 9, 2008

(51) Int. Cl. H01L 29/205

(52) U.S. Cl. 257/192; 257/E29.091

(57) ABSTRACT

A high linearity doped-channel FET, comprises a substrate, a buffer layer, a channel layer and a cap layer stacked downwardly thereon. The cap layer has a source region, a drain region with a distance apart from the source region and a gate region formed by removing part of the cap layer between the source region and the drain region. A source electrode and a drain electrode are respectively formed on the source region and the drain region, and a gate electrode is formed on the gate region, wherein the source region and the drain region of the cap layer are respectively provided with an opening for forming a good ohmic contact between the source region and the drain region with the channel layer respectively.

### FIELD OF THE INVENTION

The invention relates, in general, to III-V semiconductor field effect devices, and more particularly, to semiconductor field effect devices having the metal of the source electrode and the drain electrode easily formed good ohmic contacts.

### BACKGROUND OF THE INVENTION

For a conventional III-V semiconductor, as shown in FIG. 1, the uses of doped InGaAs channel layer and undoped AlGaAs barrier layer often lead to extremely high contact resistance on the source region and the drain region which will significantly deteriorate the performance of the device. Therefore how to reduce the contact resistance is very important.

Besides, the performance of a semiconductor device is also affected by different operating temperatures. Curves 11 and 12 as shown in FIG. 2 respectively reveal the characteristic of conductance (Gm) vs. gate current (Vg) of the prior field effect transistor (FET) measured at the temperature of 25° C. and 125° C. respectively. As shown in FIG. 2, the conductance (Gm) of the prior device varies apparently while the temperature goes up; and the stability of the prior device is bad at different operating temperatures.

Referring to FIG. 3, curve 21 shows source resistance variable with gate current of the conventional FET. It can be observed that source resistance (Rs) changes significantly with the gate current varying so that the performance of the device will be also degraded.

Therefore, in order to solve the above stated problem, a novel FET is developed in accordance with the present invention.

### SUMMARY OF THE INVENTION

An object of the present invention is to provide a doped-channel field effect transistor device, which provides a good ohmic contact between the metal of the source electrode and the drain electrode with the channel layer respectively so that the performance of the transistor will not be affected by the temperature, and the device can be kept on a high linearity while operating the device.

Another object of the present invention is to provide a high linearity doped-channel FET, through the improvement of the ohmic contact between source and drain metal with the doped-channel respectively, the performance of each transistor made on the same wafer will be maintained with high uniformity.

To achieve the above stated objects, the high linearity doped-channel field effect transistor in accordance with the present invention comprises a substrate, a buffer layer formed on the substrate, a barrier layer formed on the buffer layer, a channel layer formed on the barrier layer, a barrier layer formed on the channel layer and a cap layer formed on the barrier layer. The cap layer has a source region, a drain region with a distance apart from the source region and a gate region formed by removing part of the cap layer between the source and the drain region. A source electrode and a drain electrode are respectively formed on the source region and the drain region, and a gate electrode is formed on the gate region, wherein the source region and the drain region of the cap layer are respectively provided with an opening for forming a good ohmic contact between the source region and the drain region with the channel layer respectively.

It is a feature of the invention that the opening is extended to the barrier layer of the channel layer.

For further understanding the invention, a detailed description is provided below with reference to examples and in accompanying with drawings so as to illustrate embodiments and effects thereof.

### BRIEF DESCRIPTION OF DRAWINGS

FIG. 1 is a cross-sectional view of a structural portion of a conventional FET device.

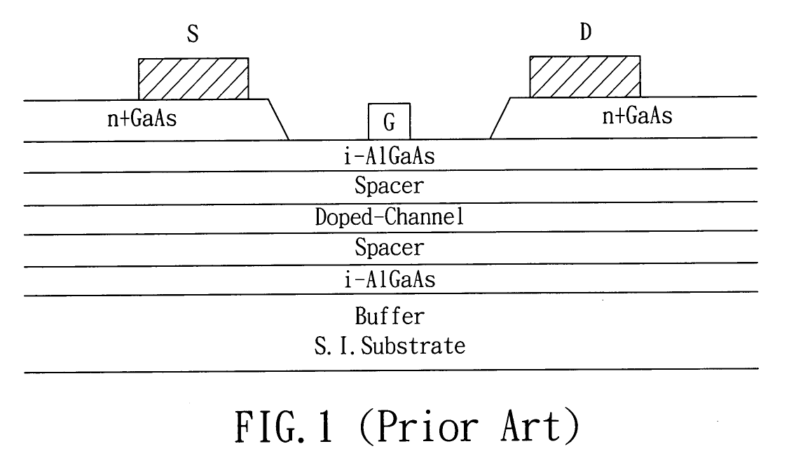

FIG. 2 is showing curves of Gm vs. Vg measured at the temperature 25° C. and 125° C. of prior FET.

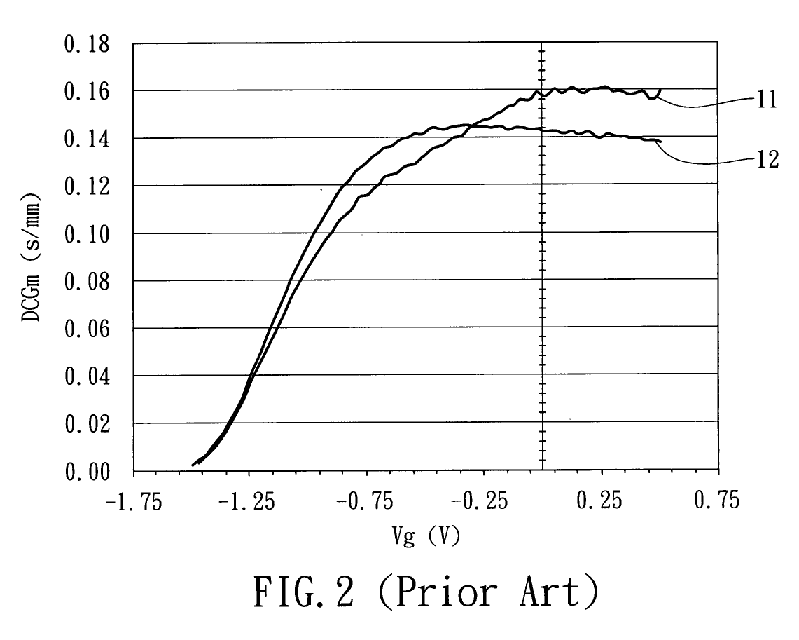

FIG. 3 is the curve of source resistance vs. gate current of prior FET.

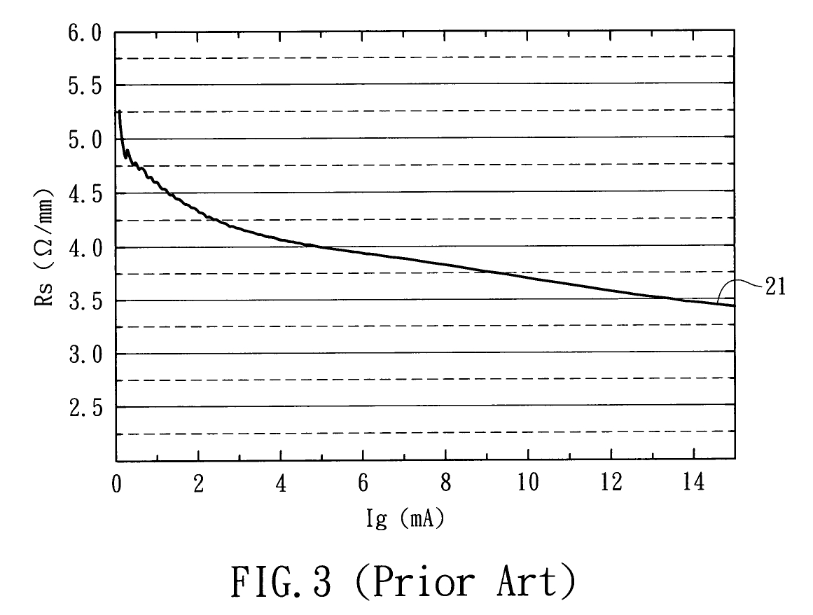

FIG. 4 is a cross-sectional view illustrating the epitaxial layer structure of a doped-channel FET device of a preferred embodiment in accordance with the present invention.

FIG. 5A shows a schematic view of a series of devices experimented with different depths of opening in accordance with persent invention.

FIG. 5B is a table comparing the contact resistances between the prior device and devices with different depths of opening formed on the cap layer in accordance with present invention at the temperature of 25° C. and 100° C.

FIG. 6 is showing curves of the contact resistances of source and drain on doped-channel FET in accordance with present invention measured at different temperature.

FIG. 7 shows the different curves of sources resistance (Rs) vs. gate current (Ig) between the prior art and the present invention.

### DETAILED DESCRIPTION OF THE INVENTION

The present invention disclosed a doped-channel FET device, which overcomes the problems of high resistance from making ohmic contact of the prior art; thereby reduces the effect of temperature to the performance of the device and significantly enhances the uniformity of the performance of the devices on the same wafer.

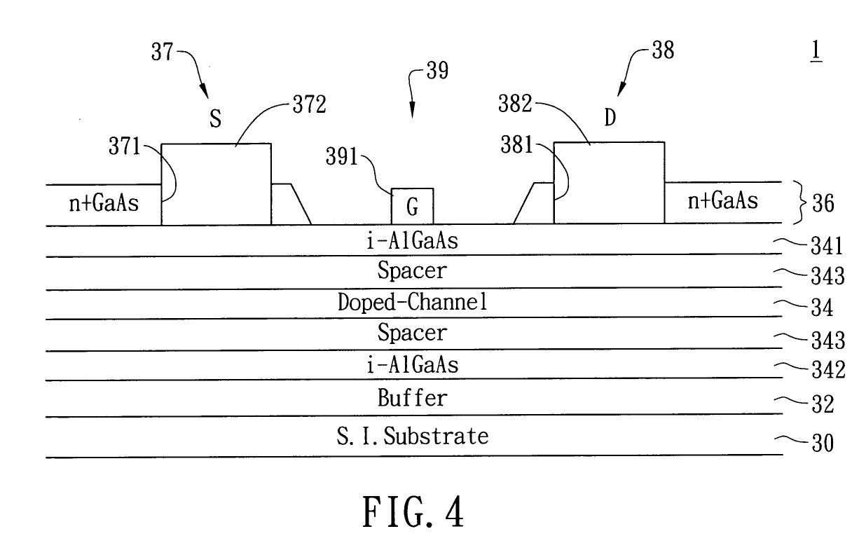

FIG. 4 illustrates a cross-sectional view of the epitaxial layer structure of a doped-channel FET device of a preferred embodiment in accordance with the present invention. It is basically a vertically stacked-layer structure, which generally comprises a substrate 30, a buffer layer 32, a channel layer 34 and a cap layer 36.

The material of the substrate 30 is comprised of semi-insulating (SI) gallium arsenide (GaAs), and that of the buffer layer 32 is also comprised of gallium arsenide grown on the SI GaAs substrate 30 by conventional epitaxial technique such as Molecular Beam Epitaxy (MBE) or Metal-organic Chemical Vapor Deposition (MOCVD).

The channel layer 34 is a doped-channel layer formed on the GaAs buffer layer 32. The channel layer 34 is generally a doped lower band-gap material which forms a so-called Pseudomorphic layer by growing an InGaAs layer thereon. The purpose of doping is to enhance carrier concentration of the channel layer. The top and the bottom of the channel layer 34 are respectively provided with a barrier layer 341, 342, which is a high band-gap material such as AlGaAs. A thin GaAs spacer layer 343 is inserted between the upper and lower of the barrier layer 341, 342 with the channel layer 34 respectively so that the quality of InGaAs channel layer 34 will not be affected by the AlGaAs thereof. Furthermore, because between the AlGaAs and the GaAs, there is a high etching selectivity, the upper AlGaAs barrier layer 341 is also considered as an etching stop layer.

The cap layer 36 is formed on the upper barrier layer 341. The material of the cap layer 36 is primarily the GaAs, which is a high doping concentration so as to reduce the subsequent contact resistance of ohmic contact of the metal. The cap layer 36 is also for preventing the oxidation of the AlGaAs barrier layer 341 due to exposing to the air.

The cap layer 36 further comprises a source region 37, a drain region 38 with a distance apart from the source region 37 and a gate region 39 formed by removing part of the cap layer 36 between the source region 37 and the drain region 38. The AlGaAs barrier layer 341 mentioned above is the etching stop layer. A gate electrode 391 is formed on the gate region 39 on which a Schottky contact is formed by metal and upper AlGaAs barrier layer 341. The carrier concentration and the conductivity of the channel layer will be modulated by Schottky barrier controlled by step-up gate voltage.

The source region 37 and the drain region 38 are respectively provided on the cap layer 36 with a source opening 371 and a drain opening 381 by conventional etching techniques such as wet or dry etching. A source metal 372 and a drain metal 382 are respectively formed within the source opening 371 and a drain opening 381 for forming a good Ohmic contact between the source 372 and drain 382 with doped-channel layer 34 respectively so as to reduce the contact resistance therebetween.

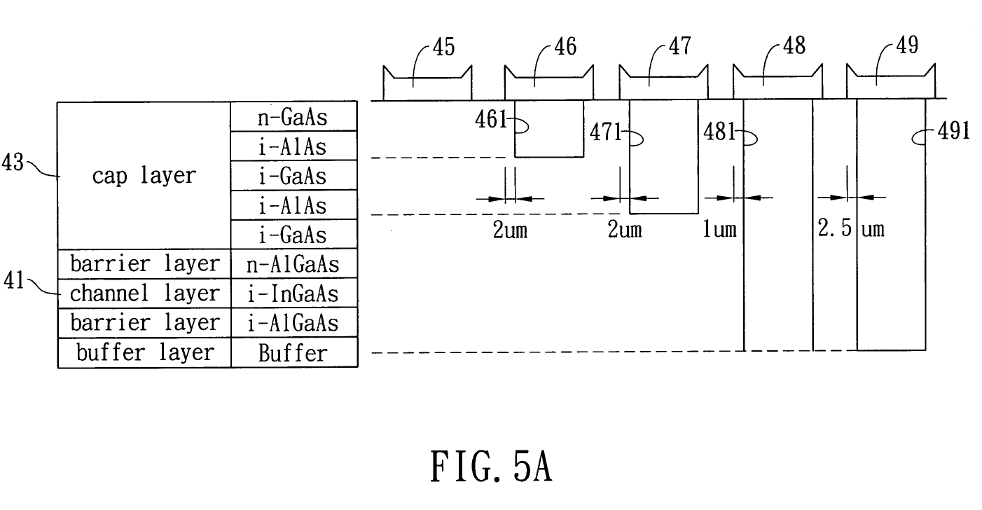

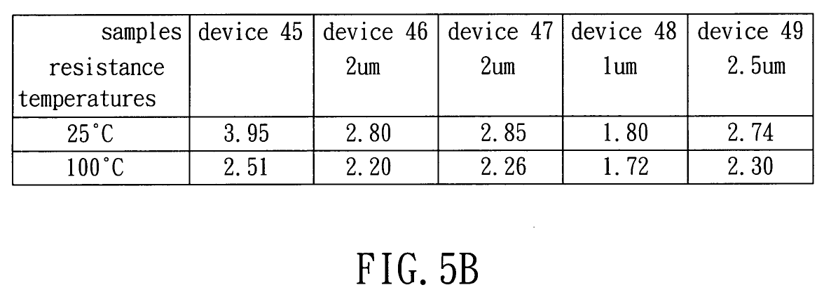

Through the experiments, the present invention found that the variation of Ohmic contact resistance has a close relationship with the depth of the opening. FIG. 5 is a schematic view of a series of openings of the cap layer with different depths on the devices, wherein the device 45 in prior art lacks an opening on the cap layer, while devices 46-49 is with different depths 461˜491 of the opening. As shown in FIG. 5, an epitaxial structure used by the experiment is also illustrated which comprises an active layer 41 (comprising the channel layer and upper and lower barrier layer) and structured cap layer 43. It is noted that in order to comply with experimental requests, the AlAs etching stops are purposely inserted into the cap layer 43 to precisely control the etching depth so as to make a study of the influence of different depths of opening on the contact resistance.

FIG. 5B is a table comparing the contact resistances between the prior device 45 and devices 46˜49 with different depths of opening formed on the cap layer 43 in accordance with present invention at the temperature of 25° C. and 100° C. From the results of experiments, it can be found that when the depth of the opening is extended into the channel layer, Ohmic resistance and rate of temperature changing can be apparently diminished. Meanwhile, the result also found that the widths of margin of the openings will affect Ohmic resistance. For instance, the widths of margin of the openings of the devices 48, 49 are 1 μm and 2.5 μm respectively, and the device 48 with the margin about 1 μm has lower resistance.

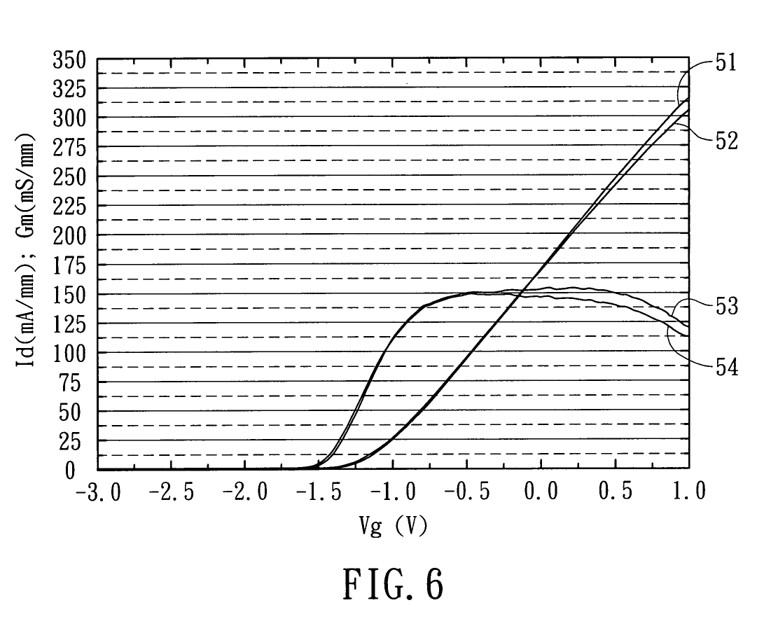

Now referring to FIG. 6, FIG. 6 is showing the curves of the contact resistances of source and drain on doped-channel FET in accordance with present invention measured at different temperatures, wherein the curves 51, 52 illustrate the drain current (Id) variable with the gate voltage (Vg) measured at the temperature of 25° C. and 100° C. respectively, and the curves 53, 54 reveal the conductance (Gm) variable with the gate voltage (Vg). As shown in FIG. 6, when the opening of the cap layer is used to form the Ohmic contact, the contact resistance of metal can be reduced and the curves of the device will not vary significantly due to the raise of the temperature, so that it can stabilize the device operating at different temperatures.

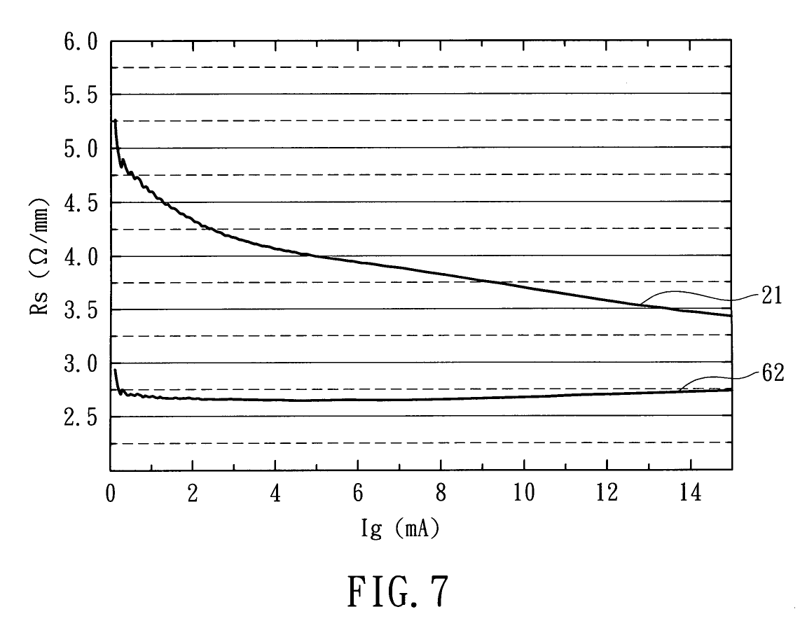

FIG. 7 further shows the curves changing of sources resistance (Rs) vs. gate current (Ig) between the prior art and the present invention. Curve 21 is the Rs-Ig curve of Ohmic contact directly formed without the opening on cap layer in prior art while the curve 62 is the Rs-Ig curve of Ohmic contact measured under the device with the opening on cap layer. Comparing the curves 21 and 62, it can be found that source resistance (Rs) of the device does not vary with the gate current (Ig) so that the device still has high linearity relationship under the operation of different gate current.

Therefore, the present invention provides a novel structure for the FET device, which can not only reduce Ohmic contact resistance but also improve the stability of the Doped-channel FET operating at high temperature thereby to manufacture high linearity FET device and to enhance the uniformity of the devices on the chip.

In summary, based on the above description and drawings, the invention can achieve its objects, providing a high linearity doped-channel FET, which is novel, useful and applicable to the semiconductor industry.

1. A high linearity Doped-Channel FET, comprising:
a substrate;
a buffer layer, formed on the substrate;
a channel, formed on the buffer layer;
a cap layer, formed on the channel layer, including a source region, a drain region with a distance apart from the source region and a gate region formed by removing part of the cap layer between the source and the drain region;
a source electrode, formed on the source region;
a drain electrode, formed on the drain region; and
a gate electrode, formed on the gate region,
wherein the source region and the drain region of the cap layer are respectively provided with an opening for forming a good ohmic contact between the source region and the drain region with the channel layer respectively.

2. The FET of claim 1, wherein the opening is extended to the channel layer.

3. The FET of claim 1, wherein the top and the bottom of the channel layer are respectively provided with a barrier layer.

4. The FET of claim 3, wherein the material of the barrier layer is a high band-gap material.

5. The FET of claim 4, wherein the material of high band-gap is AlGaAs.

6. The FET of claim 1, wherein the material of the channel layer is InGaAs.

7. The FET of claim 1, wherein the material of the cap layer is GaAs.

8. The FET of claim 1, wherein the opening of cap layer is formed by etching techniques.

9. The FET of claim 1, wherein a margin of the opening has a width bigger than 0 μm, and small than 10 μm.

10. The FET of claim 9, wherein the width of the margin of the opening is about 1 μm.
